(19) United States
(12) Patent Application Publication
(10) Pub. No.: US 2020/0011932 A1
(43) Pub. Date: Jan. 9, 2020

(54) BATTERY CAPACITY FADING MODEL USING DEEP LEARNING

(71) Applicant: NEC Laboratories America, Inc., Princeton, NJ (US)

(72) Inventors: Ali Hooshmand, San Jose, CA (US); Hossein Hosseini, Seattle, WA (US); Ratnesh Sharma, Fremont, CA (US)

(73) Assignee: NEC Laboratories America, Inc., Princeton, NJ (US)

(21) Appl. No.: 16/458,825

(22) Filed: Jul. 1, 2019

Related U.S. Application Data
(60) Provisional application No. 62/694,129, filed on Jul. 5, 2018.

(51) Int. Cl. G01R 31/367; G01R 31/36; H01M 10/48; G01R 31/374

(52) U.S. Cl. CPC G01R 31/367; G01R 31/374; H01M 10/482; G01R 31/3648

(57) ABSTRACT

A battery management system is provided. The battery management system includes a memory for storing program code. The battery management system further includes a processor for running the program code to extract features from battery operation data. The processor further runs the program code to train a deep learning model to model a battery degradation process of a battery using the extracted features. The processor also runs the program code to generate, using the deep learning model, a prediction of a battery capacity degradation based on the battery operation data and a current battery capacity of the battery. The processor additionally runs the program code to control an operation of the battery responsive to the prediction of the battery capacity degradation.

### RELATED APPLICATION INFORMATION

This application claims priority to U.S. Provisional Pat. App. Pub No. 62/694,129, filed on Jul. 5, 2018, incorporated herein by reference herein its entirety.

### BACKGROUND

### Technical Field

The present invention relates to batteries and more particularly to a battery capacity fading model using deep learning.

### Description of the Related Art

Battery fading prediction is an important problem in electrical systems. Accurate prediction of capacity degradation helps both battery manufacturers for better lifetime prediction modeling and also developers for more advanced real-time energy management. The data obtained from an increasing number of electric and hybrid vehicles as well as energy storage devices can help improving the prediction models. However, the use of this wealth of data with the state of the art data analytics techniques has been very limited so far and little is known about the content with respect to lifetime prognosis. Thus, there is a need for a deep neural network strategies to monitor the behavior of lithium-ion batteries and predict the battery lifetime under different scenarios.

### SUMMARY

According to an aspect of the present invention, a battery management system is provided. The battery management system includes a memory for storing program code. The battery management system further includes a processor for running the program code to extract features from battery operation data. The processor further runs the program code to train a deep learning model to model a battery degradation process of a battery using the extracted features. The processor also runs the program code to generate, using the deep learning model, a prediction of a battery capacity degradation based on the battery operation data and a current battery capacity of the battery. The processor additionally runs the program code to control an operation of the battery responsive to the prediction of the battery capacity degradation.

According to another aspect of the present invention, a computer-implemented method is provided for battery management. The method includes extracting, by a processor, features from battery operation data The method further includes training, by the processor, a deep learning model to model a battery degradation process of a battery using the extracted features. The method also includes generating, by the processor using the deep learning model, a prediction of a battery capacity degradation based on the battery operation data and a current battery capacity of the battery. The method additionally includes controlling, by the processor, an operation of the battery responsive to the prediction of the battery capacity degradation.

According to yet another aspect of the present invention, a computer program product is provided for battery management. The computer program product includes a non-transitory computer readable storage medium having program instructions embodied therewith. The program instructions are executable by a computer to cause the computer to perform a method. The method includes extracting, by a processor of the computer, features from battery operation data. The method further training, by the processor, a deep learning model to model a battery degradation process of a battery using the extracted features. The method also includes generating, by the processor using the deep learning model, a prediction of a battery capacity degradation based on the battery operation data and a current battery capacity of the battery. The method additionally includes controlling, by the processor, an operation of the battery responsive to the prediction of the battery capacity degradation.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a block diagram showing an exemplary processing system to which the present invention may be applied, in accordance with an embodiment of the present invention;

FIG. 2 is a flow diagram showing an exemplary method for generating a battery capacity fading model using deep learning, in accordance with an embodiment of the present invention;

FIG. 3 is a flow diagram further showing block 210 of the method 200 of FIG. 2, in accordance with an embodiment of the present invention;

FIG. 4 is a diagram showing an exemplary battery capacity fading model, in accordance with an embodiment of the present invention;

FIG. 5 is a flow diagram further showing block 215 of the method 200 of FIG. 2, in accordance with an embodiment of the present invention;

FIG. 6 is a block diagram showing an exemplary deep learning architecture for battery capacity fading prediction, in accordance with an embodiment of the present invention; and

FIG. 7 shows an exemplary battery management system, in accordance with an embodiment of the present principles.

### DETAILED DESCRIPTION OF PREFERRED EMBODIMENTS

The present invention is directed to a battery capacity fading model using deep learning.

In an embodiment, the present invention provides a deep learning battery aging model that is designed to provide a more accurate battery lifetime prognosis model. The proposed model is able to use the available time series of data showing the battery performance and produce a more accurate lifetime prognosis.

In an embodiment, accurate and scalable prediction solutions are provided which use deep learning components (e.g., LSTM units), and which will consider both cycle-related and calendar aging features as well as interactions between different parameters.

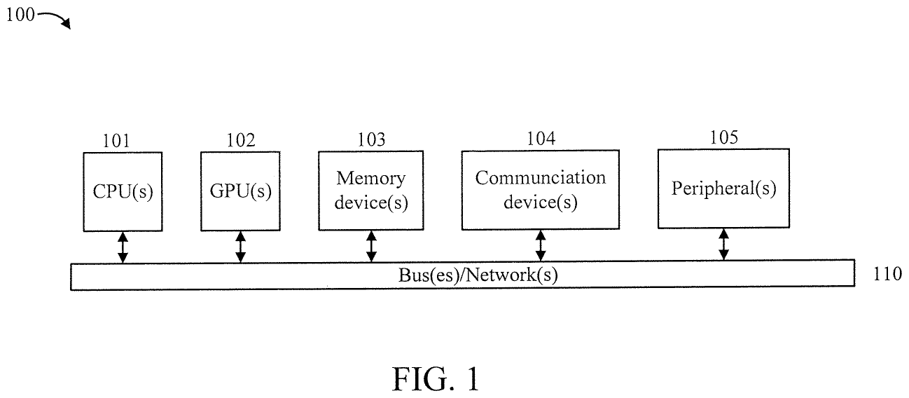

FIG. 1 is a block diagram showing an exemplary processing system 100 to which the present invention may be applied, in accordance with an embodiment of the present invention. The processing system 100 includes a set of processing units (e.g., CPUs) 101, a set of GPUs 102, a set of memory devices 103, a set of communication devices 104, and set of peripherals 105. The CPUs 101 can be single or multi-core CPUs. The GPUs 102 can be single or multi-core GPUs. The one or more memory devices 103 can include caches, RAMs, ROMs, and other memories (flash, optical, magnetic, etc.). The communication devices 104 can include wireless and/or wired communication devices (e.g., network (e.g., WIFI, etc.) adapters, etc.). The peripherals 105 can include a display device, a user input device, a printer, an imaging device, and so forth. Elements of processing system 100 are connected by one or more buses or networks (collectively denoted by the figure reference numeral 110).

In an embodiment, memory devices 103 can store specially programmed software modules in order to transform the computer processing system into a special purpose computer configured to implement various aspects of the present invention. In an embodiment, special purpose hardware (e.g., Application Specific Integrated Circuits, and so forth) can be used to implement various aspects of the present invention. For example, in an embodiment, the memory devices, along with one of the processors, can be specially programmed to implement a signature generator, detectors, a knowledge database, prediction model, and alarm generator as described herein.

Of course, the processing system 100 may also include other elements (not shown), as readily contemplated by one of skill in the art, as well as omit certain elements. For example, various other input devices and/or output devices can be included in processing system 100, depending upon the particular implementation of the same, as readily understood by one of ordinary skill in the art. For example, various types of wireless and/or wired input and/or output devices can be used. Moreover, additional processors, controllers, memories, and so forth, in various configurations can also be utilized as readily appreciated by one of ordinary skill in the art. These and other variations of the processing system 100 are readily contemplated by one of ordinary skill in the art given the teachings of the present invention provided herein.

Moreover, it is to be appreciated that various figures as described below with respect to various elements and steps relating to the present invention that may be implemented, in whole or in part, by one or more of the elements of system 100.

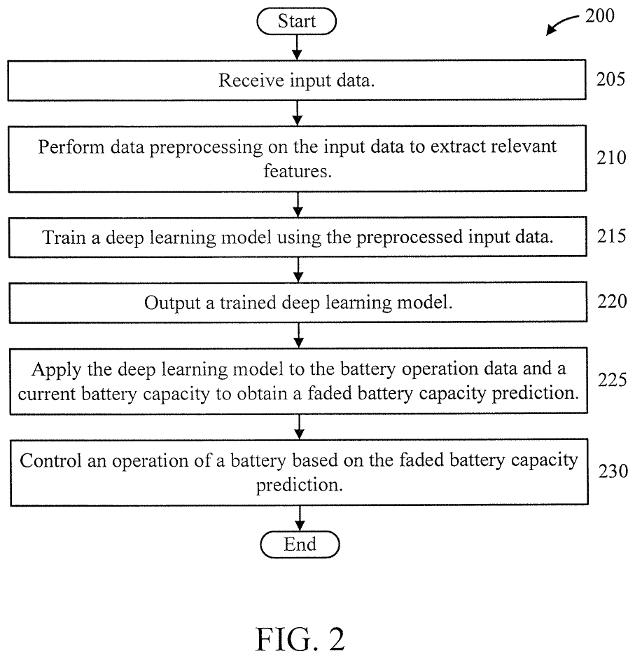

FIG. 2 is a flow diagram showing an exemplary method 200 for generating a battery capacity fading model using deep learning, in accordance with an embodiment of the present invention.

At block 205, receive input data. In an embodiment, the input data can include, for example, but is not limited to, the following:
datetime: data retrieve date and time
bat_pw_in: charging power (unit is watts)
bat_pw_out: discharging power (unit is watts)
bat_temp: maximum temperature of battery (unit is Celsius)
bat_soc: state of charge.

While various units are described in relation to the preceding, other units can be used, as readily appreciated by one of ordinary skill in the art.

At block 210, perform data preprocessing on the input data to extract relevant features.

At block 215, train a deep learning model using the preprocessed input data.

At block 220, output a trained deep learning model. The trained model can be used in production for prediction of battery capacity degradation, and can be further fine-tuned if new data becomes available. The deep learning model provides bat_learning_cap, which is the latest capacity measured, e.g., semi-annually.

At block 225, apply the deep learning model to the battery operation data and a current battery capacity to obtain a faded battery capacity prediction.

At block 230, control an operation of a battery based on the faded battery capacity prediction. For example, the battery can be switched out for another battery, and so forth as operations that can be performed responsive to model predictions.

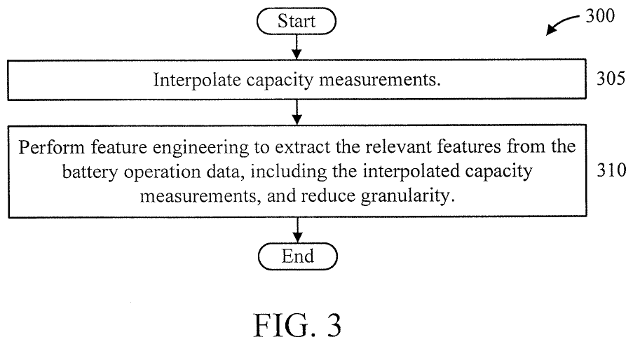

FIG. 3 is a flow diagram further showing block 210 of the method 200 of FIG. 2, in accordance with an embodiment of the present invention.

At block 305, interpolate capacity measurements. In this way, intermediate data points can be obtained.

At block 310, perform feature engineering to extract the relevant features from the battery operation data, including the interpolated capacity measurements, and reduce granularity.

A further description will now be given regarding block 305, in accordance with one or more embodiments of the present invention.

Unlike battery operation features that have been measured every five minutes, the battery capacity is measured at about once every six months. This causes the machine learning model to have relatively few data points to train with. In order to improve the training performance, we propose to interpolate the capacity measurement data at times for which battery operation features are available. We develop a weighted average interpolation method. In this method, each missing point is replaced with a weight average of available measurements, while the weight of a measurement is proportional to inverse of the time difference of the interpolated time and the measurement time. The weights are normalized so that their sum is equal to 1. Let tᵢ, i ∈ [0, k], are measurement times, and s be a time at which we want to interpolate the capacity. The interpolation rule is defined as follows:

$${x}_{s} = {\sum }_{i = 0}^{k} {w}_{i} {x}_{i} , {w}_{i} ∝ \frac{1}{\vert s - {t}_{i} \vert} , {\sum }_{i = 0}^{k} {w}_{i} = 1.$$

A further description will now be given regarding block 310, in accordance with one or more embodiments of the present invention.

To model the battery degradation process, we use a collection of real time series data obtained during the 3 years of operation of approximately 4000 different Behind The Meter (BTM) battery installations. TABLE 1 shows a sample battery aging dataset. During the operation, date and time, battery charge power, discharge power, ambient temperature, and state of charge (SOC) data are recorded every 5 minutes. The battery capacity is measured with a smaller frequency, mostly every 6 months. The capacity is constant until the next measurement is performed. Other time periods can be used, depending upon the implementation and any specific requirements.

TABLE 1

| | | | | | Measured |
|---|---|---|---|---|---|
| | Charge | Discharge | Temperature | SOC | capacity |
| Datetime | power (kW) | power (kW) | (C) | (%) | (kWh) |
| 5/8/2013 | 0.0 | 0.9 | 28 | 87 | 29 |
| 7:04 PM | | | | | |
| 5/8/2013 | 0.0 | 1.1 | 28 | 85 | 29 |
| 7:09 PM | | | | | |
| . . . | . . . | . . . | . . . | . . . | . . . |

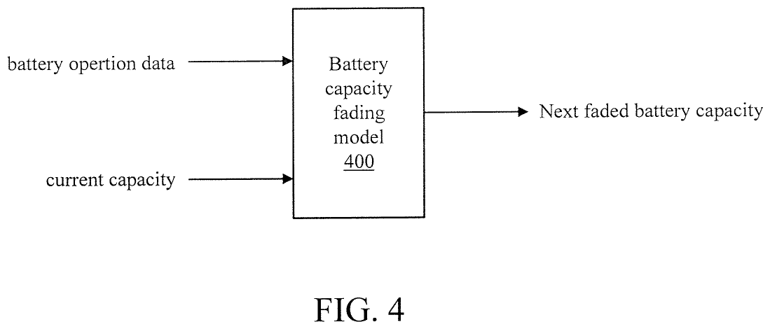

We are required to develop a battery capacity fading model that receives battery operation data as well as the current capacity of the battery to estimate the new faded capacity. FIG. 4 is a diagram showing an exemplary battery capacity fading model 400, in accordance with an embodiment of the present invention.

The battery capacity fading model 400 receives the battery operation data and current capacity as inputs to the model 400, and provides a next faded capacity as an output of the model 400.

It means we have six months recorded operation information with 5 minute sampling time as the input data to estimate the new capacity of the battery. On the other hand, the input data size for every six months window is too large (6 months×30 days×24 hours×12 samples per hour×5 features per sample=259,200) in comparison to the number of data samples. Hence, we need to prepare the input data into a more meaningful, useful, and compact shape.

A description will now be given regarding battery capacity fading processes, in accordance with one or more embodiments of the present invention.

Battery capacity fading is a nonlinear and also complicated phenomenon created by two aging means, e.g. cyclic aging and calendar aging. The cyclic aging is caused by charge and discharge actions over the course of the battery's lifetime. It has been observed that the battery capacity is directly affected by charge/discharge characteristics such as state-of charge (SOC), charge and discharge rates, and energy throughput. The calendar aging happens when battery remains idle. Calendar aging is a function of storage SOC. Batteries encounter both cyclic and calendar aging on a daily basis, so a capacity degradation model combining both effects can improve the accuracy of the assessment.

A description will now be given regarding feature extraction, in accordance with one or more embodiments of the present invention.

As discussed above, we utilize the knowledge of cyclic and calendar aging processes to transfer the raw battery operation input data. Since a BTM battery installation usually experiences a complete operation cycle in weekly manner, we use the raw data and extract the features associated with cyclic and calendar aging for each week of operation separately.

Cyclic aging is a function of parameters such as average SOC, delta SOC, charge and discharge rates, ambient temperature, and throughput. First, the average weekly SOC will be the arithmetic average of the SOC values recorded during the related week with 5 minute sampling time. To calculate the delta SOC, we calculate the difference between the initial SOC at the beginning of the week and its final SOC. Charge and discharge rates are calculated based on their normalized rates for each charge and discharge event respectively, neglecting the idle periods. The average charge and discharge rates for the weekly profile will be the arithmetic average of calculated rates:

$${c}_{rate}^{w} = {\sum }_{t ∈ week} \frac{\vert {P}_{cha} ( t ) \vert \times Δ T ( t )}{Cap ( t )} .$$

where cᵣₐₜₑ^{w} is the weekly averaged charge rate, |P_{cha}(t)| is the absolute value of t th charging event with the duration of ΔT(t), and Cap(t) is the current battery capacity. To calculate the discharge rate, the charging events should be replaced with discharging events. Weekly throughput, .h^{w}, of the battery is calculated by:

$${Wh}^{w} = {\sum }_{t ∈ week} \vert P ( t ) \vert \times Δ T ( t )$$

where |P(t)| is the absolute value of t-th charge and discharge events with the duration of ΔT (t). Finally, the average weekly temperature is simply calculated based on the arithmetic average of recorded temperature data during the related week.

Calendar aging is a function of battery life, its experienced idle time, and the SOC values during the idle times. The battery life feature is defined by the week number for which we extract the weekly features. The weekly idle time, T_{idle}^{w}, is the weekly accumulated shelf time in which the battery is not charge and discharged. Ultimately, the idle SOC is calculated based on the arithmetic average of SOC values during the idle times.

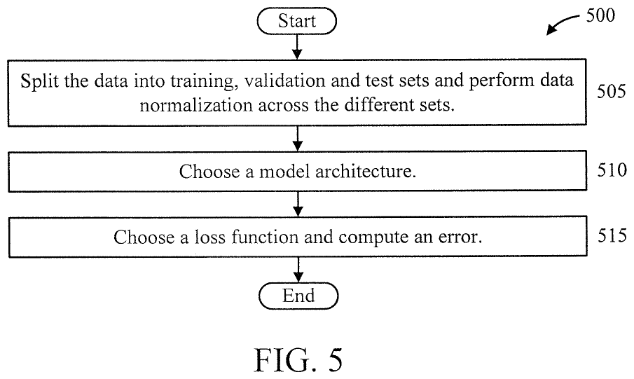

FIG. 5 is a flow diagram further showing block 215 of the method 200 of FIG. 2, in accordance with an embodiment of the present invention.

At block 505, split the data into training, validation and test sets and perform data normalization across the different sets.

At block 510, choose a model architecture.

At block 515, choose a loss function and compute an error.

A further description will now be given regarding data splitting per block 505, in accordance with one or more embodiments of the present invention.

We randomly split the data into three sets of training data (70%), validation data (15%) and test data (15%). Of course, other splits can be used. Validation data is used to set the hyperparameters and to choose the best performing model. The model performance is then tested on test data. Training features are normalized to have zero mean and unit variance. Validation and test features are then normalized using the mean and standard deviation of the training data.

A further description will now be given regarding choosing a model architecture per block 510, in accordance with one or more embodiments of the present invention.

Recurrent neural network (RNN) is a class of artificial neural networks with sequential units and hence is suitable for learning dynamic temporal behaviors in time-series data. One particular class of RNNs is Long Short Term Memory (LSTM) networks, which is specifically designed to capture long term dependencies. An LSTM network maintains a time-varying state that can be interpreted as the memory of the network, and is updated at each time step by incorporating the new input sample. The time-varying memory enables the model to capture more complex temporal behaviors compared to stationary models such as autoregressive models.

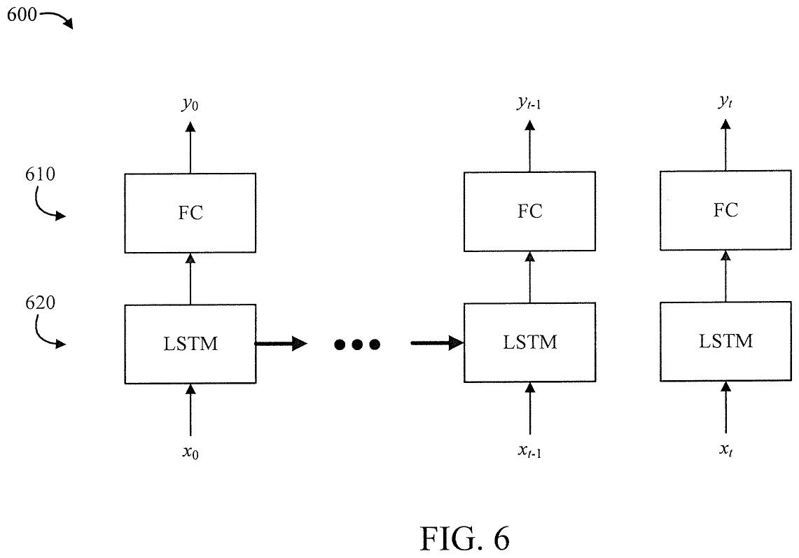

We use time-series data of battery operations and predict battery capacity fading. The battery operations, such as charging or discharging rate, idle SoC time and temperature, can combine in a complex way to make long term impacts on the battery capacity. Therefore, an LSTM-based model is a suitable tool to learn such variable-lag temporal dependencies. The features extracted by the LSTM model are then fed to a one-layer fully-connected network to make the final prediction. FIG. 6 is a block diagram showing an exemplary deep learning architecture 600 for battery capacity fading prediction, in accordance with an embodiment of the present invention. The LSTM units 610 and FC layer 620 are set to have 50 and 100 hidden neurons.

In FIG. 6, each input sample xᵢ, is a set of features extracted from one week of data, and yᵢ are the change in capacity in corresponding week. Some of yᵢ values are actual ones and some are interpolated. The one sample per one week is a trade-off between keeping model complexity to be low and also to preserve the information in data. The number of time steps is about 150 samples, which helps the LSTM model to capture the temporal correlations in data.

A further description will now be given regarding choosing a loss function and computing an error per block 515, in accordance with one or more embodiments of the present invention.

The model is trained to minimize the Mean Absolute Error (MAE) with respect to the interpolated capacity values. The validation and test errors, however, are computed based on actual capacity measurements. For this, we aggregate the deviations from interpolated measurements in one sampling period (six month) and report it as the error of the corresponding time period. We then compute the mean absolute values of all deviations as the final error.

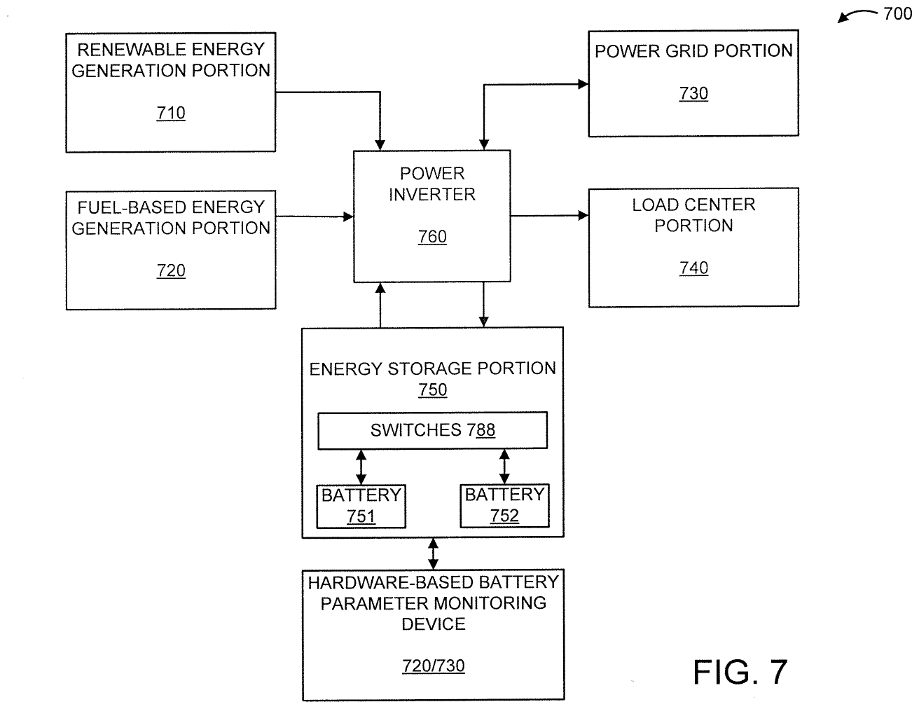

FIG. 7 shows an exemplary battery management system 700, in accordance with an embodiment of the present principles.

The system 700 includes a processor-based battery aging model generator 710, a processor-based battery control system 720, and a hardware-based battery parameter monitoring device 730. The processor-based battery control system 720 is enabled to perform energy management functions and, thus, the terms “processor-based battery control system” and “energy management system” are used interchangeably herein.

The processor-based battery aging model generator 710 generates a battery capacity fading model as described herein.

The processor-based battery control system 720 interfaces with the system in which the modeled battery is deployed. The processor-based battery control system 720 performs actions responsive to the model generated by the processor-based battery aging model generator 710.

For example, actions performed by the processor-based battery control system 720 can include, but are not limited to, providing a warning/indication to one or more personnel and/or to the power system in which the modeled battery is used (e.g., to initiate the personnel and/or power system to take an action in response to the model, and so forth), performing a battery management operation, providing long-term planning direction and economical operation and analysis based on how battery is operated, and so forth. It is to be appreciated that the processor-based battery control system 720 can perform any type of energy management function including, but not limited to, setting and/or changing a charge/discharge profile of a battery.

The aforementioned warning/indication can be provided via, for example, but not limited to, email, text, a visual-based indicator, a tactile-based indicator, a sound-based indicator, and so forth. The visual-based indicator can be, for example, but is not limited to, a flashing light (located in a place in which applicable personnel can see the light and act upon the indication that its use provides), and so forth. The tactile-based indicator can be, for example, but is not limited to, a vibration generating device (e.g., as found in many mobile phones and pagers), and so forth. The sound-based indicator can be, for example, but is not limited to, a speaker, and so forth.

The battery management operation can include, but is not limited to, switching and/or otherwise initiating a switching from one battery (e.g., that the model has indicated and/or otherwise identified as being near its end-of-life or having some other aging related deficiency as determined by the model (e.g., loss of capacity greater than a threshold amount, and so forth) to another that is in better condition (e.g., a new or newer battery, a battery having a different capacity and/or size, and so forth), and so forth. The switching from one battery to another can be made through one or more hardware-based switches (e.g., relays) that are controlled by the processor-based battery control system 720 and/or are responsive to a command initiated by the processor-based battery control system 720.

The preceding actions that can be taken by the processor-based battery control system 720 are merely illustrative and, thus, other actions can also be performed by the processor-based battery control system 720 as readily appreciated by one of ordinary skill in the art given the teachings of the present principles provided herein, while maintaining the spirit of the present principles.

The hardware-based battery parameter monitoring device 730 monitors (e.g., measures) certain battery parameters used to generate a battery aging model in accordance with the present principles. The battery parameters can include, but are not limited to, any of the following: temperature; charging/discharging rates; maximum/minimum state of charge (SOC); battery capacity; temperature; and so forth. The hardware-based battery parameter monitoring device 730 can read battery charge/discharge profiles and provide the profiles to the battery aging model generator 710 in order for the generator 710 to estimate battery degradation. The processor-based battery control system 720 can set a new charge/discharge profile or change a current charge/discharge profile to a different charge/discharge profile based on a battery aging model generated in accordance with the present principles.

A description will now be given regarding various competitive/commercial advantages of the present invention.

One advantage is the use of deep neural networks to improve accuracy and efficiency. The improvements in accuracy and efficiency gained by using deep neural networks has the following two applications: (1) better monitoring of battery behavior to provide real-time suggestions for users to improve the product lifetime, and (2) providing a more accurate prediction for manufacturers to decide on warranty rules for their products.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as SMALLTALK, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

Having described preferred embodiments of a system and method (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

What is claimed is:

1. A battery management system, comprising:
a memory for storing program code; and
a processor for running the program code to
extract features from battery operation data;
train a deep learning model to model a battery degradation process of a battery using the extracted features;
generate, using the deep learning model, a prediction of a battery capacity degradation based on the battery operation data and a current battery capacity of the battery; and
control an operation of the battery responsive to the prediction of the battery capacity degradation.

2. The battery management system of claim 1, wherein the processor further runs the program code to interpolate additional data points using a weighted average interpolation method applied to the battery operation data.

3. The battery management system of claim 1, wherein the weighted average interpolation method replaces a missing data point in the battery operation data with a weighted average of a plurality of available data points, with a weight used for the weighted average being proportional to an inverse of a time difference of an interpolation time of the missing data point and a measurement time of the plurality of available data points.

4. The battery management system of claim 1, wherein the deep learning model comprises at least one Long Short-Term Memory for each of the features.

5. The battery management system of claim 1, wherein battery operation data comprises a charging power, a discharging power, a battery maximum temperature, and a current battery state of charge.

6. The battery management system of claim 1, wherein the deep learning model comprises a battery cycling degradation model, and the features comprise an ambient temperature, a throughput, a charging rate, a discharging rate, and a state of charge.

7. The battery management system of claim 1, wherein the deep learning model comprises a calendar aging degradation model, and the features comprise idle times and state of charge values during the idle times.

8. The battery management system of claim 1, wherein the deep learning model is a battery cycling degradation and calendar aging degradation model, the features for the battery cycling degradation comprise an ambient temperature, a throughput, a charging rate, a discharging rate, and a state of charge, and the features for the calendar degradation model comprise idle times and state of charge values during the idle times.

9. The battery management system of claim 1, wherein the deep learning model is trained based on different interactions between the extracted features.

10. The battery management system of claim 1, wherein the processor further runs the program code to set or change a charging/discharging profile for the battery based on the prediction.

11. The battery management system of claim 1, further comprising one or more hardware based switches and another battery, wherein the processor further runs the program code to initiate a switching, using the one or more hardware based switches, from the battery to the other battery based on the prediction.

12. The battery management system of claim 1, wherein the battery operation data is divided into a training data set, a validation data set, and a test data set, wherein the validation date set is used to set hyperparameters of the deep learning model.

13. A computer-implemented method for battery management, comprising:
extracting, by a processor, features from battery operation data;
training, by the processor, a deep learning model to model a battery degradation process of a battery using the extracted features;
generating, by the processor using the deep learning model, a prediction of a battery capacity degradation based on the battery operation data and a current battery capacity of the battery; and
controlling, by the processor, an operation of the battery responsive to the prediction of the battery capacity degradation.

14. The computer-implemented method of claim 13, further comprising interpolating additional data points using a weighted average interpolation method applied to the battery operation data.

15. The computer-implemented method of claim 13, wherein the weighted average interpolation method replaces a missing data point in the battery operation data with a weighted average of a plurality of available data points, with a weight used for the weighted average being proportional to an inverse of a time difference of an interpolation time of the missing data point and a measurement time of the plurality of available data points.

16. The computer-implemented method of claim 13, wherein the deep learning model comprises at least one Long Short-Term Memory for each of the features.

17. The computer-implemented method of claim 13, wherein battery operation data comprises a charging power, a discharging power, a battery maximum temperature, and a current battery state of charge.

18. The computer-implemented method of claim 13, wherein the deep learning model comprises a battery cycling degradation model, and the features comprise an ambient temperature, a throughput, a charging rate, a discharging rate, and a state of charge.

19. The computer-implemented method of claim 13, wherein the deep learning model comprises a calendar aging degradation model, and the features comprise idle times and state of charge values during the idle times.

20. A computer program product for battery management, the computer program product comprising a non-transitory computer readable storage medium having program instructions embodied therewith, the program instructions executable by a computer to cause the computer to perform a method comprising:
extracting, by a processor of the computer, features from battery operation data;
training, by the processor, a deep learning model to model a battery degradation process of a battery using the extracted features;
generating, by the processor using the deep learning model, a prediction of a battery capacity degradation based on the battery operation data and a current battery capacity of the battery; and
controlling, by the processor, an operation of the battery responsive to the prediction of the battery capacity degradation.
